(19) United States
(12) Patent Application Publication
(10) Pub. No.: US 2015/0076541 A1
(43) Pub. Date: Mar. 19, 2015

(54) LIGHT-EMITTING DEVICE

(71) Applicant: KABUSHIKI KAISHA TOSHIBA, TOKYO (JP)

(72) Inventor: Asako IKEDA, Tokyo (JP)

(73) Assignee: KABUSHIKI KAISHA TOSHIBA, TOKYO (JP)

(21) Appl. No.: 14/194,588

(22) Filed: Feb. 28, 2014

(30) Foreign Application Priority Data
Sep. 13, 2013 (JP) 2013-191189

(51) Int. Cl. H01L 33/50; H01L 33/62; H01L 33/56

(52) U.S. Cl. CPC H01L 33/507; H01L 33/56; H01L 33/62
USPC 257/98; 257/99

(57) ABSTRACT

A light-emitting device includes a first and second lead frame spaced from each other. A light-emitting element is mounted on the first lead frame and electrically connected to the first and second lead frames. A first frame body is disposed on the first lead frame and the second lead frame and surrounds the light-emitting element. A resin including a phosphor is disposed on the light-emitting element and fills a frame formed by the first frame body. A second frame body surrounds the first frame body. The second frame body has an upper surface that higher than an upper surface of the first frame body.

### CROSS-REFERENCE TO RELATED APPLICATION

This application is based upon and claims the benefit of priority from Japanese Patent Application No. 2013-191189, filed Sep. 13, 2013, the entire contents of which are incorporated herein by reference.

### FIELD

Embodiments described herein relate generally to light-emitting devices.

### BACKGROUND

The development of a lighting device using a light emitting diode (LED) as a light source is important. For example, a light-emitting device using a combination of a blue LED and a phosphor is small and long-life and is suitable for a light source of a lighting device. However, in this type of light-emitting device, the spectrum of an emitted light changes depending on the optical path length of the LED light that excites the phosphor. As a result, color unevenness that depends on the direction in which the light is emitted develops as result of optical path length differences.

### DESCRIPTION OF THE DRAWINGS

FIGS. 1A and 1B are schematic diagrams depicting a light-emitting device according to an embodiment.

FIGS. 2A to 2D are schematic sectional views, each depicting a process for manufacturing the light-emitting device according to the embodiment.

FIGS. 3A and 3B are schematic diagrams depicting a light-emitting device according to a modified example of the embodiment.

FIGS. 4A and 4B are schematic sectional views, each depicting a light-emitting device according to another modified example of the embodiment.

FIGS. 5A and 5B are schematic sectional views, each depicting a light-emitting device according to still another modified example of the embodiment.

FIG. 6 is a schematic sectional view depicting a light-emitting device according to a comparative example.

### DETAILED DESCRIPTION

An exemplary embodiment provides a light-emitting device that can suppress color variation resulting from differences in the direction in which a light is emitted from the light-emitting device.

In general, according to one embodiment, a light-emitting device includes a first lead frame, a second lead frame that is electrically insulated from the first lead frame, a light-emitting element mounted on the first lead frame and electrically connected to the first lead frame and the second lead frame, a first frame body portion surrounding the light-emitting element, a resin disposed on the light-emitting element and filling a frame formed by the first frame body portion, and a second body portion surrounding the first frame body portion. The resin contains a phosphor which, when excited by a wavelength of a light emitted by the light-emitting element, emits a light having a wavelength that is different from the wavelength of the light emitted by the light-emitting element, and the second frame body portion has an upper surface at a height above an upper surface of the first frame body portion.

Hereinafter, embodiments will be described with reference to the drawings. Identical portions in the drawings are identified with common reference numerals and the detailed descriptions thereof are omitted as appropriate, and only different portions may be described. Incidentally, the drawings are schematic or conceptual diagrams, and the depicted relationships between the thickness and the width of each portion, the size ratio between different portions, etc. are not necessarily identical to the relationship, the size ratio, etc. of an actual device. Moreover, even when the same portion is depicted in different drawing, the dimensions and ratio thereof may be different in different drawings.

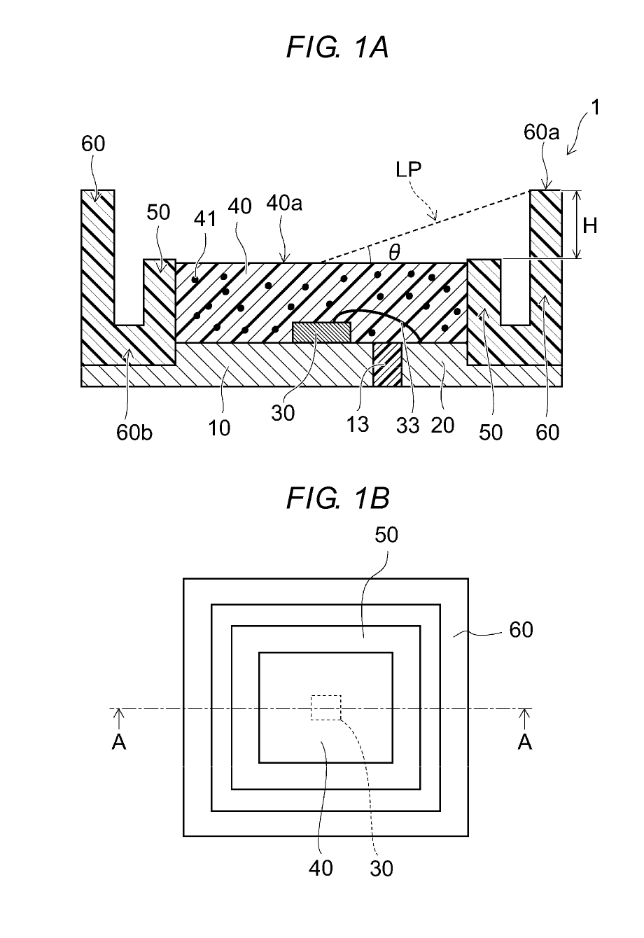

FIGS. 1A and 1B are schematic diagrams depicting a light-emitting device 1 according to an embodiment. FIG. 1A is a sectional view taken on the line A-A depicted in FIG. 1B. FIG. 1B is a plan view depicting a shape viewed from above.

As depicted in FIG. 1A, the light-emitting device 1 includes a first lead frame (hereinafter, a lead frame 10), a second lead frame (hereinafter, a lead frame 20), a light-emitting element 30 mounted on the lead frame 10, and a resin 40 covering the light-emitting element 30. The lead frame 20 is disposed beside the lead frame 10 in a side by side manner. The lead frame 10 is disposed in a position away from the lead frame 20, and an insulator 13 is provided between the lead frame 10 and the lead frame 20. As a result, the lead frame 10 and the lead frame 20 are electrically insulated from each other.

The light-emitting element 30 is, for example, a vertical blue LED that passes a drive current between a light-emitting face and a rear face. The light emitting-element 30 is electrically connected to the lead frame 10 and the lead frame 20. The light-emitting element 30 is mounted in such a way that, for example, the rear face opposite to the light-emitting face is mounted to the lead frame 10. Then, for example, a metal wire 33 is bonded between an electrode provided in part of the light-emitting face and the lead frame 20 to thereby connect the electrode and the lead frame 20 electrically.

Furthermore, as depicted in FIG. 1B, the light-emitting device 1 includes a first frame body (hereinafter, a frame body 50) surrounding the light-emitting element 30 and a second frame body (hereinafter, a frame body 60) surrounding the frame body 50. The frame bodies 50 and 60 are provided in such a way as to lie astride the lead frame 10 and the lead frame 20 and contacting the lead frame 10 and the lead frame 20.

The frame body 50 is filled with resin 40 which covers the light-emitting element 30. The resin 40 contains a base material that allows an emitted light of the light-emitting element 30 to pass therethrough and a phosphor 41 that is excited by the emitted light from the light-emitting element 30 and consequently emits a light at a wavelength which is different from the wavelength of the emitted light from the light-emitting element 30. Incidentally, “allowing a light to pass therethrough” includes not only allowing all of the emitted light of the light-emitting element 30 to pass therethrough but also absorbing part thereof. Thus, the base material need not be completely transparent to light emitted by the light-emitting element 30 and may absorb and/or scatter portions of the light emitted by the light-emitting element 30.

The base material of the resin 40 is, for example, silicone resin and allows a visible light to pass therethrough. The phosphor 41 is, for example, a YAG phosphor and absorbs a blue light emitted from the light-emitting element 30 and emits a yellow light.

The frame body 60 is provided outside the frame body 50. The height of the frame body 60 above each lead frame (lead frames 10 and 20) is greater than the height of frame body 50. For example, a height at which a line LP connecting an inner edge of a top end 60a of the frame body 60 to the center of a top face 40a of the resin 40 does not intersect the frame body 50. Moreover, as depicted in FIG. 1A, the frame body 60 may be connected to the frame body 50 in a lower part 60b which may be in contact with the lead frame 10 and the lead frame 20.

The frame bodies 50 and 60 include a component that reflects the emitted lights of the light-emitting element 30 and the phosphor 41—that is, reflects light at wavelengths of the light emitted by light-emitting element 30 and the phosphor 41. As the frame bodies 50 and 60, for example, epoxy resin in which minute particles of titanium oxide are dispersed or silicone white resin is used. In addition, the frame bodies 50 and 60 reflect the emitted light of the light-emitting element 30 and the emitted light of the phosphor 41 contained in the resin 40.

On the other hand, surfaces of the lead frame 10 and the lead frame 20 (e.g., bottom surfaces in FIG. 1A) that are opposite to the surface on which the light-emitting element 30 is mounted (upper surfaces in FIG. 1A), are exposed. Accordingly, light-emitting device 1 can be mounted on a circuit substrate, for example, by using the exposed surfaces (e.g., bottom surfaces in FIG. 1A) of the lead frames 10 and 20 as a bonding pad.

Moreover, preferably, the faces of the lead frames 10 and 20 on which the light-emitting element 30 is mounted include a component, for example, silver (Ag), whose degree of reflection of the emitted lights of the light-emitting element 30 and the phosphor 41 is higher than the degree of reflection of a core of each lead frame.

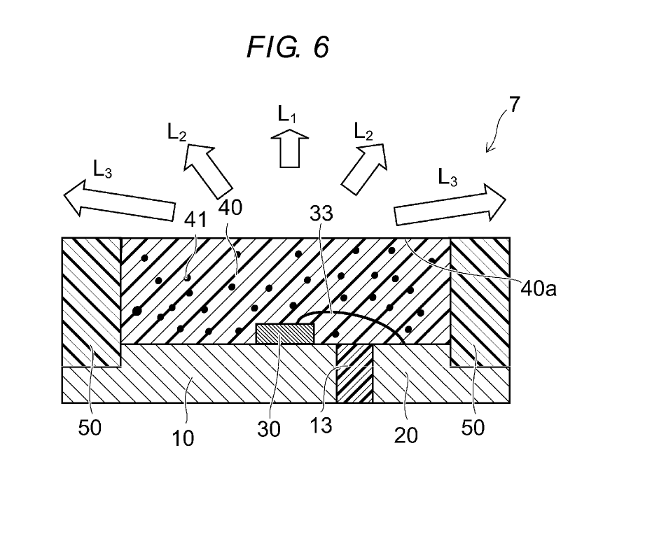

Next, with reference to FIG. 6, the characteristics of the light-emitting device 1 will be described. FIG. 6 is a schematic sectional view depicting a light-emitting device 7 according to a comparative example.

As depicted in FIG. 6, the light-emitting device 7 includes a light-emitting element 30 mounted on a lead frame 10, a frame body 50 surrounding the light-emitting element 30, and a resin 40 with which the frame body 50 is filled. However, the light-emitting device 7 does not include an outside frame body 60 surrounding the frame body 50.

Arrows L₁ to L₃ depicted in FIG. 6 schematically illustrate the light distribution characteristics of the light emitted from the light-emitting device 7. The length of each arrow represents the ratio of a yellow light in the output from light-emitting device 7. The longer the arrow in FIG. 6, the higher the ratio of the yellow light in the output from light-emitting device 7.

The blue light emitted from the light-emitting element 30 passes through the resin 40 and is emitted from a top face 40a to the outside. Part of the blue light is absorbed by a phosphor 41 that is dispersed in the resin 40 and is converted into a yellow light. As a result, the longer the optical path length of a blue light in the resin, the more the light is attenuated by phosphors 41. Thus, the intensity of the blue light that propagates through the resin 40 in a transverse direction (±X directions, that is the left-right directions in FIG. 6) is reduced. As a result, the ratio of the yellow light in the light L₃ that is emitted sideways (in an oblique direction, rather than perpendicular to top surface 40a) becomes higher than the ratio of the yellow light in the light L₁ that is emitted upward (Z direction), and a directional color unevenness develops in the light output from light-emitting device 7.

On the other hand, in the light-emitting device 1 according to the embodiment, the frame body 60 provided outside the frame body 50 surrounding the light-emitting element 30 reflects the light L₃ that is emitted sideways in an oblique direction. Then, the light reflected by the frame body 60 is mixed into the lights L₁ and L₂ that are emitted in the Z direction. As a result, in the light-emitting device 1, color unevenness that depends on the direction in which the light is emitted can be suppressed.

Also, by simply blocking the light L₃ that is emitted in a transverse direction with the frame body 60, color unevenness can be reduced. That is, the frame body 60 may absorb the blue light emitted from the light-emitting element and the yellow light emitted from the phosphor 41. Specifically, as the frame body 60, black resin containing carbon particles, for example, may be used.

Furthermore, the height H of the frame body 60 depicted in FIG. 1A is set with consideration given to an emission angle of the light L₃ in which the ratio of the yellow light is high. For example, an upper limit of the angle θ between the top face 40a of the resin 40 and the straight line LP is limited by the mounting conditions or the light distribution angle. On the other hand, a lower limit of θ is set in accordance with an acceptable range of color unevenness.

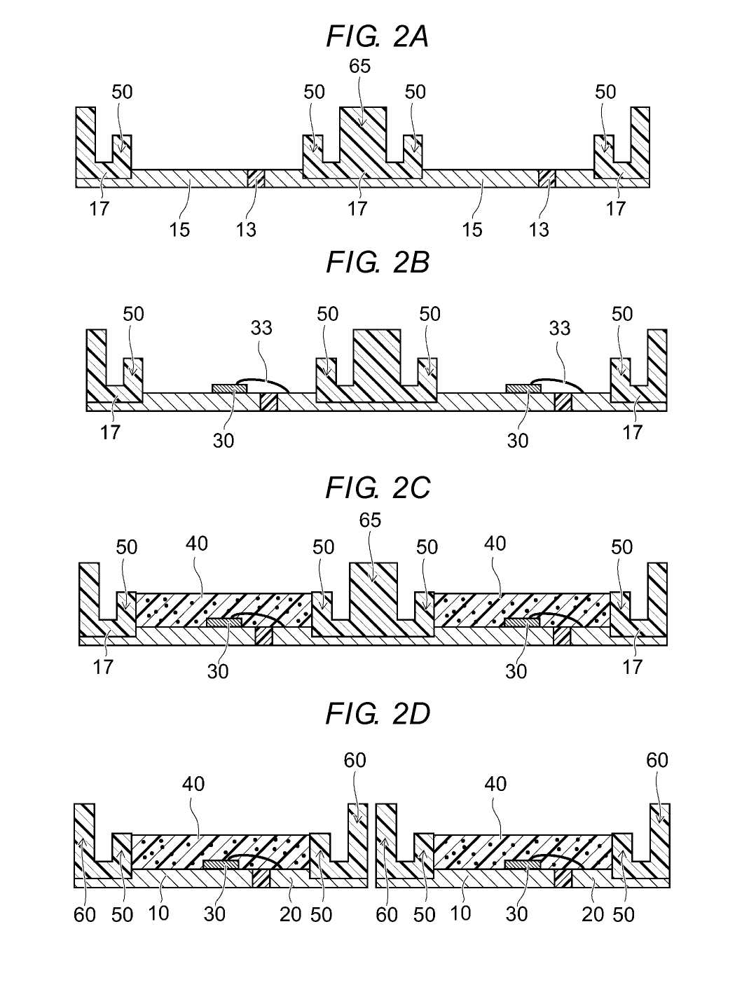

Next, with reference to FIGS. 2A to 2D, a method for producing the light-emitting device 1 according to an embodiment will be described. FIGS. 2A to 2D are schematic sectional views, each depicting a process of production of the light-emitting device 1 according to the embodiment.

As depicted in FIG. 2A, a resin frame 17 is formed on a metal plate 15. The metal plate 15 is, for example, a copper plate having a punched lead pattern. The top face of the metal plate 15 is preferably plated with a component, for example, silver (Ag), which has a high reflectivity for the emitted lights of a light-emitting element 30 and a phosphor 41. Moreover, the metal plate 15 includes an insulator 13 that provides isolation between a lead frame 10 and a lead frame 20.

The resin frame 17 is formed by using, for example, epoxy resin in which powder of titanium oxide is dispersed or silicone in such a way as to include a frame body 50 and a projection 65 that will be divided into frame bodies 60.

Next, as depicted in FIG. 2B, a light-emitting element 30 is mounted in a portion of the metal plate 15, the portion surrounded with the frame body 50. The light-emitting element 30 is firmly fixed to a portion to be processed into the lead frame 10 with a conductive paste, for example, sandwiched between the light-emitting element 30 and the portion. Then, a metal wire 33 is bonded to an electrode provided on a light-emitting face (top face) of the light-emitting element 30 and a portion to be processed into the lead frame 20.

Next, as depicted in FIG. 2C, the portion surrounded with the frame body 50 is filled with resin 40, whereby the light-emitting element 30 is encapsulated therein. The resin 40 is injected into each portion by using a potting method, for example, and is then hardened. Filling of the resin 40 may be performed in such a way that the resin 40 and the top face of the frame body 50 are on the same level or may be performed in such a way that a portion of resin 40 is higher than the top face of the frame body 50. Alternatively, filling of the resin 40 may be performed in such a way that the top face 40a of the resin 40 becomes lower than the top face of the frame body 50.

Next, as depicted in FIG. 2D, the resin frame 17 and the metal plate 15 are divided at the center of the projection 65, whereby the light-emitting device 1 is completed. The resin frame 17 and the metal plate 15 are cut by using a dicing blade, for example. By using the above-described method, a small and low-cost light-emitting device can be formed.

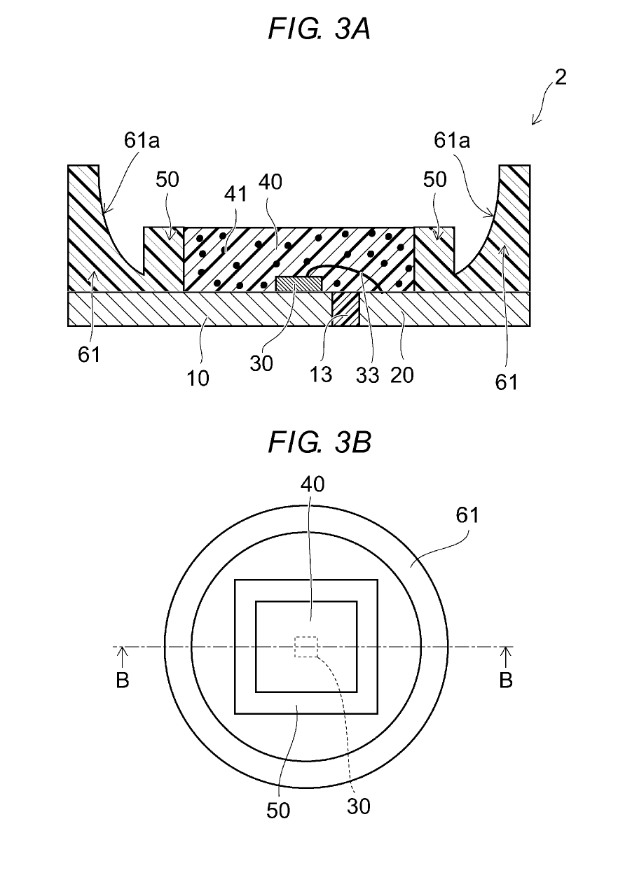

Next, with reference to FIGS. 3A to 5B, light-emitting devices 2 to 6 according to modified examples of the embodiment will be described. It should be noted that these examples are typical examples and the disclosure is not limited thereto.

FIGS. 3A and 3B are schematic diagrams depicting the light-emitting device 2 according to a modified example. FIG. 3A is a sectional view taken on the line B-B depicted in FIG. 3B. FIG. 3B is a plan view depicting a shape viewed from above.

As depicted in FIG. 3A, the light-emitting device 2 includes a lead frame 10, a lead frame 20, a light-emitting element 30 mounted on the lead frame 10, and a resin 40 covering the light-emitting element 30. The frame body 50 is filled with the resin 40.

In addition, on the outside of the frame body 50, a frame body 61 is provided. An inner surface 61a of the frame body 61 has a shape spreading in the direction (Z direction) in which a light is emitted. The inner surface 61a is, for example, a paraboloid and reflects obliquely emitted light from resin 40 toward the Z direction. As depicted in FIG. 3B, the frame body 61 can be formed into a circle.

The shape of the frame body provided outside the frame body 50 is not limited to the above example and may be any shape, and the planar shape (the shape when viewed from above, as in FIG. 3B) thereof may be a rectangular, circular, or oval shape. Moreover, the frame body 50 may also have any shape, and the planar shape thereof is not limited to a rectangular shape depicted in FIGS. 1A and 1B and FIGS. 3A and 3B.

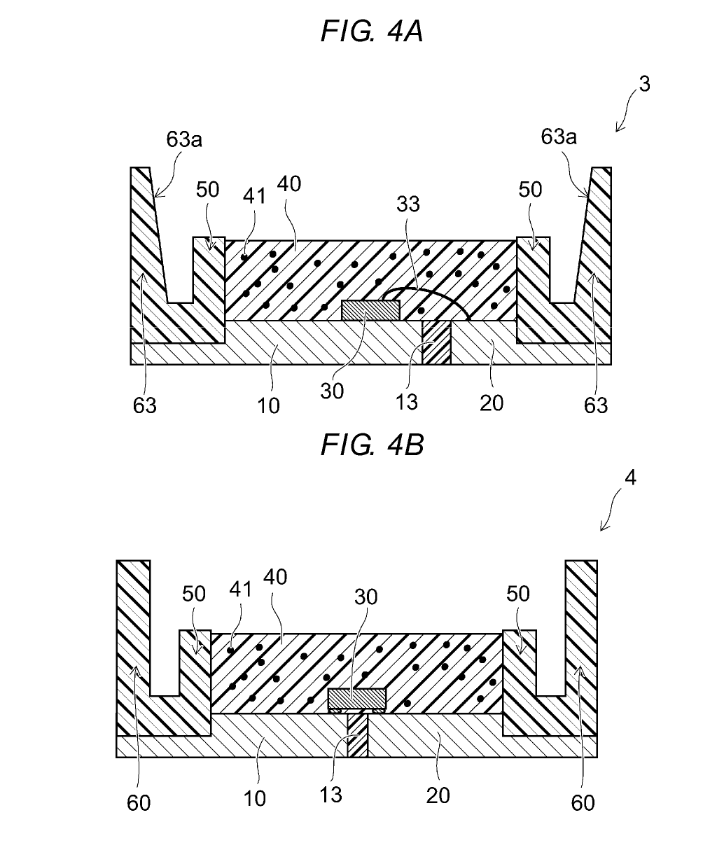

FIG. 4A is a schematic sectional view depicting light-emitting device 3. As depicted in FIG. 4A, the light-emitting device 3 includes a lead frame 10, a lead frame 20, a light-emitting element 30 mounted on the lead frame 10, and a resin 40 covering the light-emitting element 30. The frame body 50 is filled with the resin 40.

On the outside of the frame body 50, a frame body 63 is provided. An inner surface 63a of the frame body 63 has an inclination spreading in the direction (e.g., the Z direction of FIG. 4A) in which a light is emitted, and which reflects upward light that is emitted from the resin 40 sideways (in an oblique direction to the upper surface of resin 40). That is, frame body 63 has an inner surface 63a that is outwardly angled (inclined) rather than perpendicular to the upper surface of resin 40.

FIG. 4B is a schematic sectional view depicting light-emitting device 4. As depicted in FIG. 4B, the light-emitting device 4 includes a lead frame 10, a lead frame 20, a light-emitting element 30 mounted on the lead frame 10, and a resin 40 covering the light-emitting element 30. The frame body 50 is filled with the resin 40. In addition, on the outside of the frame body 50, a frame body 60 is provided.

The light-emitting element 30 includes a p-electrode and an n-electrode on a rear face opposite to a light-emitting face. In addition, the light-emitting element 30 is mounted by flip-chip bonding in such a way as to lie astride the lead frames 10 and 20. The light-emitting elements 30 described in other embodiments may be replaced with the light-emitting element 30 depicted in FIG. 4B. That is, for example, rather than using a bonding wire as depicted in FIG. 1A, flip-chip bonding may be incorporated to make an electrical connection to lead frame 20 of light-emitting device 1. Similar modifications can be incorporated into light-emitting device 2, light emitting device 3, light-emitting device 5 (described below), and light-emitting device 6 (described below) or other embodiments of the present disclosure.

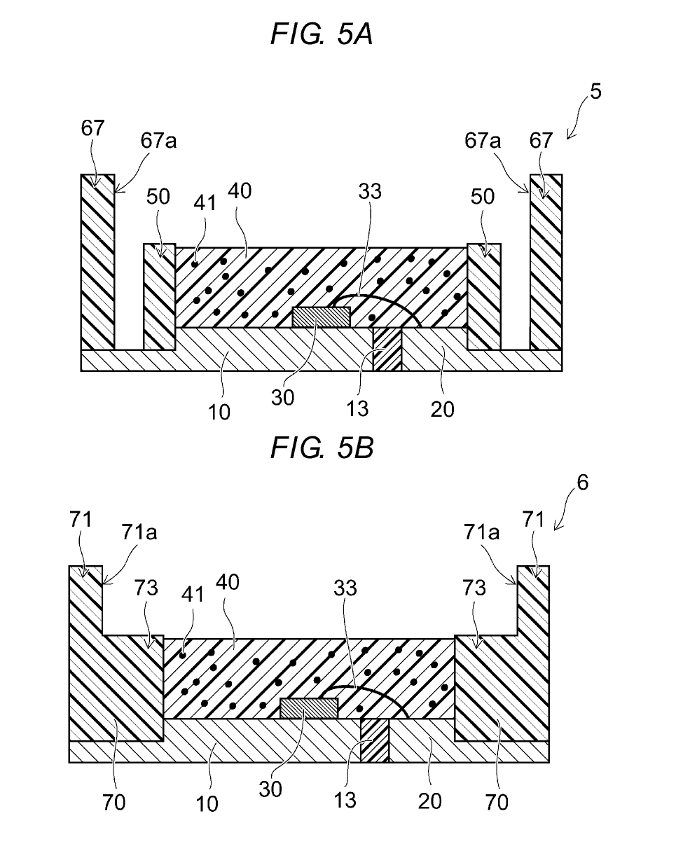

FIG. 5A is a schematic sectional view depicting the light-emitting device 5. As depicted in FIG. 5A, the light-emitting device 5 includes a lead frame 10, a lead frame 20, a light-emitting element 30 mounted on the lead frame 10, and a resin 40 covering the light-emitting element 30. The frame body 50 is filled with the resin 40.

On the outside of the frame body 50, a frame body 67 is provided. Portions of the frame body 67, the portions in contact with the lead frames 10 and 20, are formed in positions away from the frame body 50. That is, frame body 67 is spaced from frame body 50. In this example, a gap is formed between inner surface 67a of frame body 67 and frame body 50. In this example, an inner surface 67a of the frame body 67 is formed to be perpendicular to the lead frames 10 and 20, but the shape is not limited thereto. For example, similar to as depicted in FIGS. 3A and 3B and FIG. 4A, the inner surface 67a may have a shape for reflecting light in a direction (Z direction) toward which a light is to be emitted from light-emitting element 5.

FIG. 5B is a schematic sectional view depicting the light-emitting device 6. As depicted in FIG. 5B, the light-emitting device 6 includes a lead frame 10, a lead frame 20, a light-emitting element 30 mounted on the lead frame 10, and a resin 40 covering the light-emitting element 30.

In this example, a frame body 70 is provided on the lead frames 10 and 20, and the frame body 70 is filled with the resin 40. The frame body 70 includes an outer portion 71 and an inner portion 73 provided inside the outer portion 71 in step-like form—that is, outer portion 71 and inner portion 73 have different upper surface heights.

The outer portion 71 is formed to be higher than (have an upper surface height that is greater than) the inner portion 73. An inner surface 71a of the outer portion 71 may have a shape reflecting obliquely emitted light from resin 40 in the direction (Z direction) in which light is to be emitted from light emitting device 6.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light-emitting device, comprising:
a first lead frame;
a second lead frame that is electrically insulated from the first lead frame;
a light-emitting element mounted on the first lead frame and electrically connected to the first lead frame and the second lead frame;
a first frame body portion surrounding the light-emitting element;
a resin disposed on the light-emitting element and filling inside a frame formed by the first frame body portion, the resin containing a phosphor which, when excited by a wavelength of a light emitted by the light-emitting element, emits a light having a wavelength that is different from the wavelength of the light emitted by the light-emitting element; and
a second frame body portion surrounding the first frame body portion, the second frame body portion having an upper surface at a height above an upper surface of the first frame body portion.

2. The light-emitting device according to claim 1, wherein a line connecting a point at a center of an uppermost surface of the resin to a point on an upper surface of the second frame body portion does not intersect the first frame body portion.

4. The light-emitting device according to claim 1, wherein the second frame body portion has a lateral surface facing the resin that reflects light.

5. The light-emitting device according to claim 4, wherein the lateral surface of the second frame body portion has a paraboloid shape.

6. The light-emitting device according to claim 4, wherein the lateral surface of the second frame body portion is inclined at an outward angle with respect to the direction perpendicular to the uppermost face of the resin.

7. The light-emitting device according to claim 1, wherein the second frame body portion is connected to the first frame body portion by a third frame body portion that is between the first and second frame body portions.

8. The light-emitting device according to claim 7, wherein the third frame body portion has an upper surface at a height that is below the upper surface of the first frame body portion.

9. The light-emitting device according to claim 7, wherein the third frame body portion has an upper surface at height that is equal to the height of the upper surface of the first frame body portion.

10. The light-emitting device according to claim 1, wherein the first and second frame body portions are spaced from each other and not connected to each other.

11. The light-emitting device according to claim 1, wherein the light-emitting element is mounted such that the light-emitting element spans a spacing between the first and second lead frames.

12. The light-emitting device according to claim 11 wherein the light-emitting element is mounted using a flip-chip bonding technique such that the electrical connection between the light-emitting element and the second lead frame is made via an electrode disposed on a surface of the light-emitting element facing the second lead frame.

13. The light-emitting device according to claim 1, wherein the electrical connection between the light-emitting element and the second lead frame is made via a bonding wire.

14. The light-emitting device according to claim 1, wherein each of the first and second frame body portions reflects light emitted by the light-emitting element and light emitted by the phosphor.

15. A light-emitting device, comprising:
a first lead frame spaced from a second lead frame;
a light-emitting element disposed on an upper surface of the first lead frame, the light emitting element configured to emit light at a first wavelength;
a first frame body portion disposed on the first lead frame and the second lead frame, the first frame body portion, when viewed from the first direction, surrounding the light-emitting element;
a second frame body portion that is higher than the first frame body portion and disposed on the first lead frame and the second lead frame, the second frame body portion, when viewed from the first direction, surrounding the first frame body portion; and
a resin disposed on the light-emitting element and inside a frame formed by the first frame body portion.

16. The light-emitting device according to claim 15, wherein a line connecting a center point of an upper surface of the resin and an upper surface of the second frame body portion does not intersect the first frame body portion.

17. The light-emitting device according to claim 15, wherein the first frame body portion forms a rectangular shape around the light-emitting element, and the second frame body portion forms a circular shape around the first frame body portion.

18. The light-emitting device according to claim 15, further comprising a third frame body portion disposed on the first lead frame and the second lead frame and connecting the first and second frame body portions.

19. A light-emitting device, comprising:
first and second lead frames;
a light-emitting element mounted on the first lead frame;
a first frame body surrounding the light-emitting element;
a resin disposed on the light-emitting element and inside a frame formed by the first frame body, the resin containing a phosphor which, when excited by a wavelength of a light emitted by the light-emitting element, emits a light having a wavelength that is different from the wavelength of the light emitted by the light-emitting element; and
a second frame body surrounding the first frame body portion, the second frame body portion having an upper surface that is higher than an upper surface of the first frame body.

20. The light-emitting device according to claim 19, wherein a line connecting a point at a center of an uppermost surface of the resin to a point on an upper surface of the second frame body portion does not intersect the first frame body portion.
